(19) United States
(12) Patent Application Publication
(10) Pub. No.: US 2022/0232705 A1
(43) Pub. Date: Jul. 21, 2022

(54) SURFACE COMPLEMENTARY DIELECTRIC MASK FOR PRINTED CIRCUITS, METHODS OF FABRICATION AND USES THEREOF

(71) Applicant: Nano Dimension Technologies, LTD, Nes Ziona (IL)

(72) Inventors: Aviram Iancovici, Rehovot (IL); Omer Goldstein, Nes Ziona (IL)

(21) Appl. No.: 17/633,833

(22) PCT Filed: Jul. 6, 2020
(86) PCT No.: PCT/US20/40924

§ 371 Date: Feb. 8, 2022

Related U.S. Application Data
(60) Provisional application No. 62/870,922, filed on Jul. 5, 2019.

(51) Int. Cl. H05K 3/00; H05K 3/12; H05K 1/18; H05K 1/02

(52) U.S. Cl. CPC H05K 3/0005; H05K 3/125; H05K 2201/09136; H05K 3/0091; H05K 1/0271; H05K 1/185

(57) ABSTRACT

The disclosure relates to systems, methods and devices for mitigating warpage in printed circuit boards (PCBs) high-frequency connect PCBs (HFCPs), or additively manufactured electronics (AME) with surface mounted chip packages (SMT) during reflow processing for soldering the SMT to the PCB, HFCP, or AME. More specifically, the disclosure is directed to the fabrication of a surface-complementary dielectric mask, or reflow compression mask to substantially encapsulate the SMT, and mitigate warpage, and/or protect the PCB, HFCP, or AME during shipment and further manipulation or processing.

### BACKGROUND

The disclosure is directed to systems, methods and devices for a) mitigating warpage in printed circuit boards (PCBs) and high-frequency connect PCBs (HFCPs) with surface mounted chip packages (SMT) during reflow processing, and b) optional enclosing of the entire PCB with an encapsulating layer reflecting the negative image of the external layers populated PCB. More specifically, the disclosure is directed to the fabrication of a surface-complementary dielectric mask to substantially encapsulate the SMT, and mitigate warpage and optional encapsulation of the devices mounted on the PCB.

Electronic devices with small form factor are increasingly in demand in all areas of, for example: manufacture, business, consumer goods, military, aeronautics, internet of things, and others. Products having these smaller form factors rely on compact and complex PCBs with tightly spaced digital and analog circuits or chip packages placed in close proximity to each other on its surface(s). Likewise, there is an increasing demand for these (small) devices to perform a substantially larger and more complex number of electronic functions, with the shrinking (miniaturization) of these active devices, which are packaged in advanced packaging (e.g., ball-grid arrays (BGAs), micro-BGAs, quad-flat packs (QFP), and chip scale packaging (CSP)), adding to the complexity and issues associated with small form factor PCBs, OEMs demand an even greater robustness, higher quality, better fault tolerance during both processing and use, increased reliability, lower ‘parasitic’ or ‘bleeding’ interconnects, and better assembly yields associated with these (small form factor) designs.

While, due to the shrinkage in size, the terminal pitch of each SMT component, for example, a BGA (Ball Grid Array) or a CSP (Chip Size Package) mounted on the PCB has been reduced, because of the increased PCB complexity and SMT density—the number of terminals of the SMT components is increasing. These components are typically fabricated from a plurality of materials, thus making them likely to become non-uniform in internal temperature and also more likely to warp upon heating when mounting them on PCBs by using a reflow soldering process, depending on the difference in the thermal expansion coefficient between these plurality of materials, the environment and the PCB itself.

Furthermore, due to the recent tendency to reduce the thickness of PCBs (e.g., to reduce the length of via holes, which is effective in terms of routing wiring from a narrow-pitch component, and reducing the area of wirings), heating-related warping is likely for not only SMT components but also the PCB itself. In other words, as the thickness of PCBs is reduced, the board is more likely to warp, thus making the coupling to the SMTs vulnerable.

Thermal warpage is thought to be induced because of the coefficient of thermal expansion (CTE) and Young's modulus mismatches between different materials (especially following solder solidification constraining expansion and relaxation of SMT relative to the surface), either within the SMT component itself, and/or between the SMT component and the dielectric portion of the PCB. During the reflow process, SMT components are mounted together and are subjected to high temperature and severe temperature gradients. This may exacerbate the total thermal warpage. Too large warpage could induce out-of-plane alignment of solder bumps, leading to unsoldered or mechanically weakened joints. Moreover, PCB warpage can also cause the coplanarity problems of solder balls (e.g., in BGAs) by affecting the formation and shape of joints, cause thermal fatigue of solder joints under operating conditions, which may in turn, affect the solder joint reliability and lead to the failure of the electronic devices.

Furthermore, there is a need to protect the mounted devices from harsh environments, and/or offering additional capabilities by permanently incorporating the complementary dielectric mask. This dielectric mask could further include metal traces and block for input/output (I/O) of signals and heat sinking purposes.

Factors that will affect warpage can include time/temperature profile during reflow soldering process, PCB thickness, PCB topology, spatial imbalance in trace density, and other factors.

The present disclosure is directed toward overcoming one or more of the above-identified shortcomings by the use of additive manufacturing technologies and systems.

### SUMMARY

Disclosed, in various exemplary implementations, are systems and methods for mitigating warpage in printed circuit boards (PCBs), high-frequency connect PCBs (HFCPs), and additive-manufactured electronics (AME), with surface mounted chip packages (SMT) during reflow processing. More specifically, disclosed are exemplary implementations of methods, systems, and surface-complementary dielectric masks, used to substantially encapsulate SMTs coupled to an external layer of the PCB, HFCP, or additively manufactured electronics (AME), and mitigate warpage of the SMT component(s) and the PCBs HFCPs, or AMEs themselves.

In an exemplary implementation provided herein is a computerized method of mitigating warpage of an assembled PCB, HFCP, or AME during reflow processing, the method comprising: obtaining a plurality of files associated with the assembled PCB, HFCP, or AME, the assembled PCB, HFCP, or AME having an apical surface and a basal surface; using the plurality of files, fabricating a surface-complementary dielectric mask (SCDM) (interchangeable with reflow compression mask, when fabricated specifically for reflow purposes—RCM), to at least one of: the apical surface, and the basal surface; and prior to commencing the reflow processing, coupling the RCM to the at least one of: the apical surface, and the basal surface, thereby mitigating warpage during reflow processing.

In another exemplary implementation, the step of fabricating the surface-complementary dielectric mask, or RCM comprises: providing an ink jet printing system comprising: a print head, operable to dispense a (first) dielectric ink composition; a conveyor, operably coupled to the print head configured to convey a substrate to the print head; and a computer aided manufacturing (“CAM”) module including a central processing module (CPM), in communication with at least the conveyor and the (first) print head, the CPM further comprising at least one processor in communication with a non-transitory processor-readable storage medium, storing thereon a processor-readable media with a set of executable instructions that, when executed by the at least one processor cause the CPM to control the ink-jet printing system, by carrying out steps that comprise: receiving at least one file associated with the assembled PCB, HFCP, or AME; and generate a library of files, each file in the library representing a substantially 2D layer for printing the RCM (in other words, the surface-complementary dielectric mask, or reflow compression mask), wherein the CAM module is configured to control each of the conveyer, and the print head; providing the (first) dielectric ink composition; using the CAM module, obtaining a file representing a first substantially 2D layer for printing; using the print head, forming the pattern corresponding to the first substantially 2D layer represented in the file; curing the pattern; obtaining a subsequent file representing the substantially 2D layer of the RCM; using the (first) print head, forming the pattern corresponding to the subsequent layer; curing the pattern corresponding to the second dielectric ink; and once all the layers configured to form the surface-complementary dielectric mask are printed and cured, removing the substrate.

In another exemplary implementation, provided herein is a method for fabricating a surface-complementary dielectric mask (or RCM), using inkjet printer comprising: providing an ink jet printing system comprising: a first print head, operable to dispense a first dielectric ink composition; a conveyor, operably coupled to the first print head, configured to convey a substrate to the first print heads; and a computer aided manufacturing (“CAM”) module including a central processing module (CPM), in communication with at least the conveyor and the first print head, the CPM further comprising at least one processor in communication with a non-transitory processor-readable storage medium storing thereon a processor-readable media with a set of executable instructions that, when executed by the at least one processor cause the CPM to control the ink-jet printing system, by carrying out steps that comprise: receiving at least one file associated with an assembled PCB, HFCP, or AME (referring the PCB, HFCP, or AME following the reflow process) for which the RCM is sought to be fabricated; using the at least one file associated with an assembled PCB, HFCP, or AME, generating a file library comprising a plurality of files, each file representing a substantially 2D layer for printing the RCM and an associated metafile representing at least the printing order for that layer; providing the first dielectric ink composition; using the CAM module, obtaining from the library a first file representative of the first layer for printing the RCM, wherein the first file comprises printing instructions for a pattern corresponding to the first layer of the RCM; using the first print head, forming the pattern corresponding to the first dielectric ink on the substrate; curing the pattern corresponding to the first dielectric ink representation in the first layer; using the CAM module, obtaining from the library, a subsequent file representative of a subsequent layer for printing the RCM, the subsequent file comprising printing instructions for a pattern corresponding to the first dielectric ink in the subsequent RCM layer; repeating the steps of: using the first print head, forming the pattern corresponding to the first dielectric ink, to the step of using the CAM module, obtaining from the 2D file library the subsequent, substantially 2D layer, whereupon curing of the pattern corresponding to the first dielectric ink composition in the final layer, the surface-complementary dielectric mask comprises a plurality of cavities, voids, protrusions, channels, divets, or their combination, configured to complement the surface of the PCB, HFCP, or AME, substantially encapsulating any surface mounted components thereon.

In yet another exemplary implementation, the method further comprises, prior to commencing reflow, providing a housing operable to accommodate both the RCM and the PCB, HFCP, or AME to which it is coupled.

These and other features of the systems, methods and masks for the direct and continuous fabrication of a surface-complementary dielectric mask, or RCM to substantially encapsulate the SMT, and mitigate warpage, will become apparent from the following detailed description when read in conjunction with the figures and examples, which are exemplary, not limiting.

### BRIEF DESCRIPTION OF THE FIGURES

For a better understanding of the fabrication of a surface-complementary dielectric mask to substantially encapsulate the SMT, and mitigate warpage, their fabrication methods and compositions, with regard to the exemplary implementations thereof, reference is made to the accompanying examples and figures, in which:

FIG. 1 (A-J), is a depiction of the file information used and the process for fabricating the RCM:

FIG. 2, is a simplified schematic illustration of FIG. 1J;

FIG. 3A illustrates an exemplary implementation of a PCB containing various sized SMT components, with FIG. 3B showing the RCM thereof; and

FIG. 4, is a flowchart of an exemplary implementation of a typical reflow process.

### DETAILED DESCRIPTION

Provided herein are exemplary implementations of systems, methods and masks operable to mitigate warpage of PCBs and/or HFCPs with SMT components coupled thereon during reflow soldering processes.

The method, systems and masks disclosed herein make use of computerized inkjet printing systems adapted and configured for 3D printing (e.g., for inkjet printing of PCB, HFCP, or AME). The RCM, is an additive manufacturing (AM) model construction in itself, which is fabricated based on the original PCB, HFCP, or AME and SMT components manufacturing design files (e.g., Gerber, Excelon, Eagle and the like), and automatically generates a library of files for printing the RCM.

The design files for printing the surface-complementary dielectric mask (RCM) can be (assuming, but not limited to a double-sided PCB, HFCP, or AME):
Shape/outline of the printed circuit, for example, Gerber files (e.g., ODB++, RS274D, RS274X, DXF, and the like). Gerber files are a set of files containing information about each layer of the PCB to be used for production. These files can contain information on, for example one of: Top Solder paste configuration, Top Trace pattern, Bottom trace pattern, Bottom Solder paste configuration, NC Drill (containing the location and size of all drill holes, as well as hole or feature to edge dimensions, X,Y, coordinates), Board outline and details with all required dimensions and tolerances, (potentially in another file), and Fabrication Drawing (optional).
Centroid File, containing information about where each SMT component is placed on the surfaces (apical and/or basal) of the PCB, HFCP, or AME, such as the x-y position, rotation, layer, reference designator and the value/package.

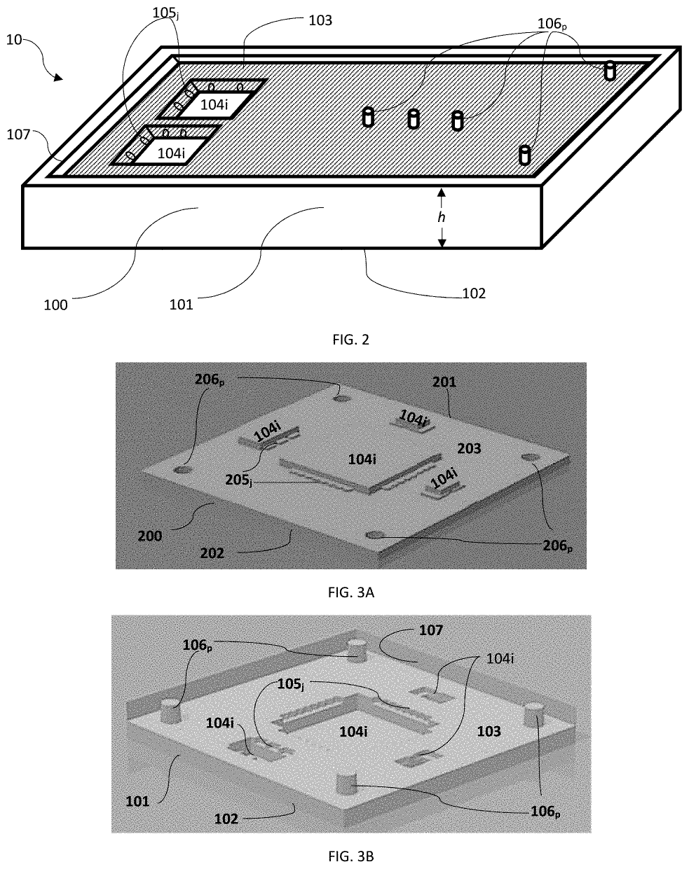

In an exemplary implementation, the surface-complementary dielectric mask can be fabricated from, for example:
Base section—fabricated using the outline file, printed to a desired height. Since thermal warpage depends on the thickness of the layer undergoing reflow soldering, the height of the base section (see e.g., h, FIG. 2), is sized and configured to mitigate any thermal warpage that may occur.
Component section—constructed from the centroid file with the creation of cavities, voids, or recesses (see e.g., 104—FIG. 2), with the addition of a desired tolerance, thus more robust for the placement of SMT components (making the cavities slightly larger than the component so it will fit).
Pads section—constructed from the outline file, with the creation and formation of cavities (see e.g., 105, FIG. 2, configured to form voids operable to accommodate the solder paste), based on the component file and the (apical/basal) solder mask location file, printed to a desired height (depth), to ensure that the surface-complementary dielectric mask (RCM), will not touch the dispensed solder paste during assembly and smear the paste before reflow processing.
Alignment section (e.g., fiducials' location)—created from the drill file (e.g., numeric control (NC) drill file, Excellon and the like) to fabricate small cylindrical protrusions (see e.g., 106ₚ, FIG. 2, configured to form protrusions sized and configured to engage the non-plated drill holes), that will act as fiducials and align the surface-complementary dielectric mask (RCM), with the complementary surface (apical and/or basal) of the PCB, HFCP, or AME. In case there are no drills in the PCB, HFCP, or AME, the outline of the board can be used to create a frame (see e.g., 107, FIG. 2), that will envelope, frame, and be fabricated to a desired depth of the PCB, HFCP, or AME. The printed surface-complementary dielectric mask (RCM), can then be printed automatically in a complementary orientation relative to the design files of the PCB, HFCP, or AME.

Currently PCB, HFCP, or AME, especially those fabricated using additive manufacturing with photopolymerisable polymers, can be affected by deformations when exposed to high temperatures, such as those time-temperature profiles experienced during the reflow soldering process (see e.g., FIG. 3), limiting assembly options to manual procedures that require time and labor. The fabricated surface-complementary dielectric mask (SCDM), or reflow compression mask (RCM) disclosed herein, can be reusable, save time and can be created using the same computerized systems that was used to initially fabricate the PCB, HFCP, or AME. In addition, precision placement of SMT components on the PCB, HFCP, or AME can be done with cameras and image processing, which would allow placement and alignment of components at the assembly phase without the need for additional costly equipment (for example, pick and place machine).

Furthermore, the surface-complimentary dielectric mask can be used as an encapsulating mold to protect the printed circuit during function, and/or shipment, creating the effect of “encapsulated” components. Also, and in an exemplary implementation, the surface-complimentary dielectric mask itself may be fabricated as a printed circuit (e.g., PCB, HFCP, AME, or flexible printed circuit (FPC)), e.g., by fabricating the base section with conductive traces (e.g., copper, silver and the like), as well as attaching SMT components, thus allowing the potential of complex multi-circuit systems fabricated using additive manufacturing. In the context of the present application, the term “encapsulated component(s)” may particularly denote a structure having one or more electronic chips (such as SMT component coupled to the PCB, HFCP, or AME) which is mounted within, but not a part of an encapsulating structure (such as the surface complementary dielectric mask) as package. Such SMT component may have a thickness smaller than thickness of the corresponding complementary cavity in the encapsulating structure (e.g., the surface complementary dielectric mask).

Furthermore, prior to reflow processing, shipment or function, the RCM coupled to the surface of the PCB, HFCP, or AME, whether in a pure dielectric form, or as a (non-testing) topology circuit, can be further secured by providing a housing operable to accommodate the PCB, HFCP, or AME, and, depending on the surfaces having the RCM coupled thereto, those coupled RCMs as well. In the context of the disclosure, the term “accommodating” refers to the component indicated as accommodating (e.g., the housing) comprising corresponding dimensions in order to correspondingly fit the accommodated component(s) (e.g., the PCB, HFCP, or AME and any surface-coupled RCM) into the interior of the accommodating component (e.g., the housing). The housing can be, for example, fabricated from metal, reinforced thermoset resin (e.g., fiberglass) and the like. Moreover, the RCM is fabricated in certain embodiments, from high-T_{g} resin incorporated to the first dielectric ink composition, for example, poly(methylmethacrylate) (PMMA), poly(ethersulfone) (PESU), poly(amide-imide) (PAI), poly(imide) (PI), their copolymers and terpolymers, reinforced with fiberglass of graphite for example).

Accordingly and in an exemplary implementation, provided herein, is a computerized method of mitigating warpage of an assembled (meaning, with at least one coupled SMT) PCB, HFCP, or AME during reflow processing, the method comprising: obtaining a plurality of files associated with each of the assembled PCB, HFCP, or AME, each having an apical surface and a basal surface and optionally, a plurality of side surfaces); using the plurality of files, fabricating a surface-complementary dielectric mask (RCM), to at least one of: the apical surface, and the basal surface; and prior to commencing the reflow processing, coupling the complementary surface dielectric mask to the at least one of: the apical surface, and the basal surface, thereby mitigating warpage during reflow processing.

In the context of the disclosure, the term “warpage” means a strain-induced non-planarity or curvature of an integrated circuit (IC) package (e.g., SMT), a PCB, HFCP, or AME, their surfaces or combination thereof, which may occur during or after assembly, for example, during the reflow process (in other words, the vertical deflection from a horizontal seating plane). The IC package, PCB, HFCP, or AME, or their combination, bows into a concave or convex (or partially convex and concave) profile, where “convex” is generally defined as bowing upward, or toward an attached die and/or stiffener, and where “concave” is generally defined as bowing downward, or away from an attached die and/or stiffener. In addition, “mitigating” in the context of the disclosure, is meant to encompass any manipulation of the surface-complementary dielectric mask (RCM), and/or the PCB, HFCP, or AME, which may lead to at least one of: a reduction of the detrimental effect on the performance of the PCB and/or any SMT component (IC) coupled thereto, and a reduction of the damage to the PCB and/or any SMT component coupled thereto following the reflow process. The term mitigating also encompasses any use of the surface-complementary dielectric mask (RCM), during at least one of: shipment (of the coupled PCB, HFCP, or AME), reflow processing, and use as a nested PCB, HFCP, or AME coupling add-on as disclosed herein (in other words the operable coupling of the original—first PCB, HFCP, or AME, to a second PCB, HFCP, or AME fabricated with at least one surface that is complementary to the surface of the first, original PCB, HFCP, or AME). For example, in an exemplary implementation of the systems and methods disclosed, the term “mitigating” means ensuring the PCB, HFCP, or AME conforms to the “IPC-9641 High Temperature Printed Board Flatness Guideline”.

For example, measuring warpage of out-of-plane deformation of a plastic ball grid array (PBGA) component can be done, for example, using thermal shadow Moiré apparatus (TherMoiré PS200) combined with a heating platform. Other methods can use full-field shadow Moiré, confocal microscopy, an array of strain gauges, finite element analysis (of temperature distribution during reflow, and/or strain gauges data).

Further, the term “file” shall include any piece of computer/processor-readable data in any form that may be shared between users. A ‘file’ may be a discrete file as it is saved by an operating system, or the ‘file’ may be a record in a database, an image or portion of an image, a block or portion of a database, or any other computer readable data that could be shared between users and used by the systems disclosed herein.

The plurality of files associated with the assembled PCB, HFCP, or AME, used in the computerized methods implemented using the systems disclosed, to mitigate warpage during reflow processing further comprise: a file configured to define an outline of the assembled PCB, HFCP, or AME; and a file configured to define dimensions and spatial arrangement of at least one surface-mounted integrated circuits (SMT) assembled on at least one of: the apical surface, and the basal surface. Moreover, the plurality of files associated with the assembled PCB, HFCP, or AME further comprise at least one of: a file configured to define spatial parameters of solder paste dispensing; and an alignment file, wherein the alignment file comprises spatial arrangement of, at least one of: a non-plated drill (through) holes (NPTH), plated thru holes (PTH), and blind vias (e.g., NPTH those used for coupling and soldering SMT components, differentiated from PTH or blind vias, both used for connecting various layers on the PCB).

Accordingly, in the methods provided herein, the step of fabricating the surface-complementary dielectric mask (RCM), used to mitigate warpage during reflow process, further comprises: providing an ink jet printing system comprising: a (first) print head, operable to dispense a (first) dielectric ink composition; a conveyor, operably coupled to the print head configured to convey a substrate to the print head; and a computer aided manufacturing (“CAM”) module including a central processing module (CPM), in communication with the print head, the CPM further comprising: at least one processor in communication with a non-transitory storage medium, storing thereon a set of executable instructions configured, when executed to cause the CPM to perform the steps of: receiving the various files disclosed herein (e.g., an ODB, an ODB++, an .asm, an STL, an IGES, a STEP (ISO 10303-21), intermediate data file (IDF) a Catia, a SolidWorks, a Autocad, a ProE, a 3D Studio, a Gerber, a Rhino a Altium, an Orcad); and generate a library of files, each file representing a substantially 2D layer for printing the surface-complementary dielectric mask (RCM), (e.g., a raster file, such as, for example: JPEG, a GIF, a TIFF, a BMP, a PDF file, or a combination comprising one or more of the foregoing), wherein the CAM module is configured to control each of the conveyer, and the print head; providing the dielectric ink composition; using the CAM module, obtaining a first substantially 2D layer; using the print head, forming the pattern corresponding to the first substantially 2D layer; curing the pattern; obtaining a subsequent, substantially 2D layer of the RCM; using the print head, forming the pattern corresponding to the subsequent layer; curing the pattern corresponding to the second dielectric ink; and once all the layers configured to form the surface-complementary dielectric mask (RCM), are printed and cured, removing the substrate.

In the context of the disclosure, the term “operable” means the system and/or the device and/or the program, or a certain element, component or step is/are fully functional sized, adapted and calibrated, comprises elements for, having the proper internal dimension to accommodate, and meets applicable operability requirements to perform a recited function when activated, coupled or implemented, regardless of being powered or not, coupled, implemented, effected, actuated, realized or when an executable program is executed by at least one processor associated with the system, method, and/or the device. In relation to systems and methods disclosed, the term “operable” also means the system and/or the circuit is fully functional and calibrated, comprises logic for, and meets applicable operability requirements to perform a recited function when executed by at least one processor.

The systems implementing the methods disclosed can further comprise several sub-systems and modules. These can be, for example: a mechanical sub-system to control the movement of the print head(s), the substrate (or the chuck to which the substrate is coupled), its heating and conveyor motions; the ink composition injection systems; the curing and/or sintering (in case conductive ink is dispensed to form the surface-complementary dielectric mask (RCM), as a stand-alone PCB, HFCP, or AME) sub-systems; a computerized sub-system with a processor (e.g., GPU and/or CPU) that is configured to control the process and generates the appropriate printing instructions and necessary files, or otherwise retrieve these files from a remote location (e.g., the 2D file library), a component placement system such as automated robotic arm (e.g., pick-and-place), a machine vision system (e.g., to measure warpage using confocal optics), and a command and control system (e.g., the CPM) to control the 3D printing.

The use of the term “module” does not imply that the components are functionality described or claimed as part of the module, or are all configured in a (single) common package. Indeed, any or all of the various components of a module, whether control logic, GPU, SATA memory drives or other components, can be combined in a single package or separately maintained and can further be distributed in multiple groupings or packages or across multiple (remote) locations and devices. Furthermore, in certain exemplary implementations, the term “module” refers to a monolithic or distributed hardware unit. Also, in the context of the disclosure provided herein, the term “dispenser” used in connection with the print-head, is used to designate the print head from which the inkjet ink drops are dispensed. The dispenser can be, for example an apparatus for dispensing small quantities of liquid including micro-valves, piezoelectric dispensers, continuous-jet print-heads, boiling (bubble-jet) dispensers, and others affecting the temperature and properties of the fluid flowing through the dispenser.

As indicated, the set of executable instructions are further configured, when executed to cause the processor to generate a library of a plurality of subsequent layers' files, whereby each subsequent layer file represents a substantially two dimensional (2D) subsequent layer for printing the surface-complementary dielectric mask (RCM), and where each subsequent layer file is indexed by printing order. In an exemplary implementation, the each layer file is configured to provide the printing instruction for a pattern of the dielectric ink representation in the layer.

In an exemplary implementation, the pattern printed in the layers is configured, upon printing the last layer in the printing order, to form voids (referring to the volume in a given 3D coordinate location) sized to accommodate the SMT components, and based on the files detailing the solder paste dispensing coordinates, and amount, adapt the generated pattern specified per layer in the 2D file library, to generate at least one file in the library, defining patterns configured to accommodate (in other words, provide the space for) the solder paste; and using. e.g., the alignment file (e.g., EAGLE), adapt the generated pattern library to generate patterns configured to form protrusions (e.g., cylindrical, or other shapes) sized and configured to engage at least one of: the non-plated drill holes (NPTH), blind vias, and plated thru holes (PTH).

In yet another embodiment, provided herein is a computerized method for fabricating a complementary dielectric surface mask for an assembled printed circuit board (PCB), high-frequency connect PCB (HFCP), or additively manufactured electronics (AME) each having at least one surface mounted component (SMT) operably coupled to at least one of: an apical surface layer, and a basal surface layer, using inkjet printer, the method comprising: providing an ink jet printing system comprising: a first print head, operable to dispense a first dielectric ink composition; a conveyor, operably coupled to the first print head, configured to convey a substrate to the first print heads; and a computer aided manufacturing (“CAM”) module including a central processing module (CPM), in communication with at least the conveyor and the first print head, the CPM further comprising at least one processor in communication with a non-transitory processor-readable storage medium storing thereon a set of executable instructions that, when executed by the at least one processor cause the CPM to control the ink-jet printing system, by carrying out steps that comprise: receiving at least one file associated with an assembled PCB, HFCP, or AME for which the RCM is sought to be fabricated; using the at least one file associated with an assembled PCB, HFCP, or AME, generating a file library comprising a plurality of files, each file representing a substantially two-dimensional (2D) layer for printing the RCM and a metafile representing at least the printing order; providing the first dielectric ink composition; using the CAM module, obtaining from the library a first file representative of the first layer for printing the RCM, wherein the first file comprises printing instructions for a pattern corresponding to the RCM; using the first print head, forming the pattern corresponding to the first dielectric ink on the substrate; curing the pattern corresponding to the first dielectric ink representation in the first layer; using the CAM module, obtaining from the library, a subsequent file representative of a subsequent layer for printing the RCM, the subsequent file comprising printing instructions for a pattern corresponding to the first dielectric ink in the subsequent layer; repeating the steps of: using the first print head, forming the pattern corresponding to the first dielectric ink, to the step of using the CAM module, obtaining from the 2D file library the subsequent, substantially 2D layer, whereupon curing of the pattern corresponding to the first dielectric ink composition in the final layer in the printing order, the RCM comprises a plurality of cavities configured to complement the surface of the PCB, HFCP, or AME, substantially encapsulating the surface mounted components thereon; and remove the substrate.

The term “chip” refers to an unpackaged, singulated, IC device. The term “chip package” may particularly denote a housing that chips come in for plugging into (socket mount) or soldering onto (surface mount) a circuit board such as a printed circuit board (PCB), thus creating a mounting for a chip. In electronics, the term chip package or chip carrier may denote the material added around a component or integrated circuit to allow it to be handled without damage and incorporated into a circuit.

The CAM module can therefore comprise: a 2D file library storing the files converted from the PCB fabrication files such as the Gerber (ODB++) and centroid files, potentially including the SMT components BOM (bill of materials) file. Moreover, the 2D library can store files converted from other file format, alternatively or additionally to the files disclosed above. These could be, for example, STEP files and/or IDF files. For example, IDF files of the PCB sought to be masked, generate two files that can be used by the CAM to generate the substantially 2D layer files. These are the *.enm file, relating to the board structure, and *.emp file, relating to the coupled components.

The term “library, as used herein, refers to the collection of the surface-complementary dielectric mask (RCM), 2D layer files derived from the various files associated with the PCB, HFCP, or AME sought to undergo reflow, be shipped or further processed, containing the information necessary to print each layer's dielectric pattern, which is accessible and used by the data collection application, and executed by the computer-readable media. The CAM further comprises a processor in communication with the file library; a memory device, or non-transitory storage device, storing a set of operational instructions for execution by the processor; a micromechanical inkjet print head or heads acting as dispensers, in communication with the processor and with the library; and a print head (or, heads') interface circuit in communication with the file library, the memory and the micromechanical inkjet print head or heads, the (2D) file library configured to provide printer operation parameters specific to a functional layer (in other words, a layer forming a part of the final fabrication).

Furthermore, the chip or chip package used in conjunction with the systems, methods and compositions described herein can be Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Ball-Grid Array (BGA), a Quad Flat No-Lead (QFN) package, a Land Grid Array (LGA) package, a passive component, or a combination comprising two or more of the foregoing.

In certain exemplary implementations, the systems provided herein further comprise a robotic arm in communication with the CAM module and under the control of the CAM module, configured to place each of the plurality of active components in its designated location, which can be fabricated by the system.

The soldering paste or soldering balls can, for example, be arranged in a grid array pattern wherein the conductive elements or solder balls are of a preselected size or sizes and are spaced apart from each other at one or more preselected distances, or pitches. Hence, the term “fine ball grid array” (FBGA) merely refers to a particular ball grid array pattern having what are considered to be relatively small conductive elements or solder balls being spaced at very small distances from each other resulting in dimensionally small spacing or pitch. As generally used herein, the term “ball grid array” (BGA) encompasses fine ball grid arrays (FBGA) as well as ball grid arrays. Accordingly and in an exemplary implementation, the pattern representative of the conductive ink printed using the methods described herein, is configured to fabricate interconnect (in other words, solder) balls. For example illustrated in FIG. 2, solder balls can be positioned in dedicated recesses 105ⱼ.

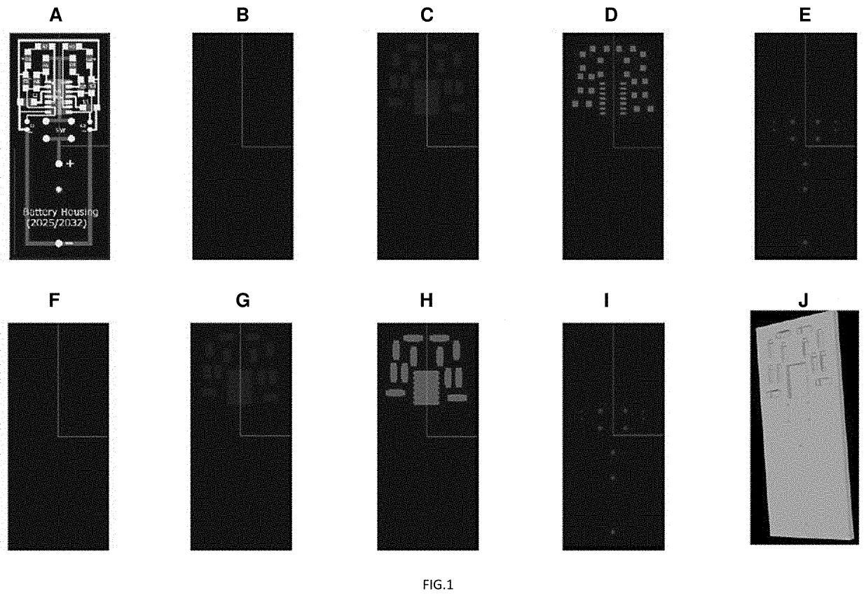

As used herein the term “complementary” means that two surface profiles, e.g., the surface profiles illustrated in FIGS. 1A and 1n FIG. 1J are sized and configured such that a surface topology profile represented by FIG. 1A can substantially nest with a complementary surface topology profile of a facing unit, for example the one illustrated in FIG. 1J. The “complementary” surfaces need not be identical. “Substantially” or “generally” does not require perfect configuration or location of features, but can vary based on, for example, manufacturing tolerances, or based on processing methodology, for example, the use of solder balls, soldering paste, or soldering powder.

For example, in circumstances where the SMT components, (e.g., Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Ball-Grid Array (BGA), a Quad Flat No-Lead (QFN) package, a Land Grid Array (LGA) package or their combination), is coupled to both the apical surface of the PCB, HFCP, or AME, the methods provided herein can further comprise the fabrication of a first dielectric surface mask, complementary to the apical surface; and a second dielectric surface mask, complementary to the basal surface. In an exemplary implementation, during the reflow processing, the PCB is sandwiched between the first and second surface complementary dielectric masks, thus providing an improved base for the PCB during the reflow processing.

Alternatively, or additionally, the additive manufacturing systems used in the methods and compositions for fabricating surface-complementary dielectric mask, can further comprise any additional number of additional functional printing heads or source materials, adapted to dispense a conductive inkjet ink, the method further comprising: providing the second conductive ink composition; using the second conductive ink print head, forming a predetermined pattern corresponding to the second conductive inkjet ink, the pattern being a 2D presentation of a connecting terminal, a bond to a lead, an interconnect ball, or a combination thereof. In these exemplary implementations, the surface-complementary dielectric mask (RCM), can be fabricated as the second PCB, HFCP, or AME, and be electrically coupled to its complementary surface on the original PCB, HFCP, or AME.

The term “forming” (and its variants “formed”, etc.) refers in an exemplary implementation to pumping, injecting, pouring, releasing, displacing, spotting, circulating, or otherwise placing a fluid or material (e.g., the conducting ink) in contact with another material (e.g., the substrate, the resin or another layer) using any suitable manner known in the art. Likewise, the term “embedded” refers to the chip and/or chip package being coupled firmly coupled within a surrounding structure, or enclosed snugly or firmly within a material or structure.

Curing the dielectric layers or pattern deposited by the appropriate dispenser as described herein, can be achieved by, for example, heating, photopolymerizing, drying, depositing plasma, annealing, facilitating redox reaction, irradiation by ultraviolet beam or a combination comprising one or more of the foregoing. Curing does not need to be carried out with a single process and can involve several processes either simultaneously or sequentially, (e.g., drying and heating and depositing crosslinking agent with an additional print head)

In an exemplary implementation, the dielectric ink composition used to form the surface-complementary dielectric mask (RCM), or mold, in the methods disclosed herein for mitigating warpage during PCBs' reflow processing comprises polyester (PES), polyethylene (PE), polyvinyl alcohol (PVOH), poly(vinylacetate) (PVA), poly-methyl methacrylate (PMMA), Poly(vinylpirrolidone), a multi-functional acrylate, or a combination comprising a mixture, a monomer, an oligomer, and a copolymer of one or more of the foregoing, which may further undergo cross-linking. In this context, crosslinking refers to joining moieties together by covalent bonding using a crosslinking agent, i.e., forming a linking group, or by the radical polymerization of monomers such as, but not limited to methacrylates, methacrylamides, acrylates, or acrylamides. In some exemplary implementation, the linking groups are grown to the end of the polymer arms.

For example, the multi-functional acrylate is at least one of a monomer, oligomer, polymer, and copolymer of: 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate or a multifunctional acrylate composition comprising one or more of the foregoing.

In an exemplary implementation, the term “copolymer” means a polymer derived from two or more monomers (including terpolymers, tetrapolymers, etc.), and the term “polymer” refers to any carbon-containing compound having repeat units from one or more different monomers.

Other functional heads may be located before, between or after the inkjet ink print heads used in the systems for implementing the methods described herein. These may include a source of electromagnetic radiation (EMR) configured to emit electromagnetic radiation at a predetermined wavelength (λ) and used to photopolymerize thus cure the multi-functional acrylates, whether alone or in the presence of photoinitiator(s). For example, the EMR source is configured to emit radiation at a wavelength of between 190 nm and about 400 nm, e.g. 395 nm which in an exemplary implementation, can be used to accelerate and/or modulate and/or facilitate a photopolymerizable dielectric ink composition. Other functional heads can be heating elements, additional printing heads with various inks (e.g., support, pre-soldering connective ink, label printing of various components for example capacitors, transistors and the like) and a combination of the foregoing.

Other similar functional steps (and therefore the support systems for affecting these steps) may be taken before or after each of the surface-complementary dielectric mask (RCM), fabrication steps (e.g., dispensing and curing). These steps may include (but not limited to): a heating step (affected by a heating element, or hot air); photobleaching (of a photoresist mask support pattern), photocuring, or exposure to any other appropriate actininc radiation source (using e.g., a UV light source); drying (e.g., using vacuum region, and/or heating element); (reactive) plasma deposition (e.g., using pressurized plasma gun and a plasma beam controller); cross linking (not by multi-functional acrylates) such as by using cationic initiator e.g. [4-[(2-hydroxytetradecyl)-oxyl]-phenyl]-phenyliodonium hexafluoro antimonate; prior to coating; annealing, or facilitating redox reactions and their combination regardless of the order in which these processes are utilized. In certain exemplary implementation, a laser (for example, selective laser sintering/melting, direct laser sintering/melting), or electron-beam melting can be used on the printed dielectric pattern. It should be noted, that sintering of conducting portions if those are added to the surface-complementary dielectric mask (RCM), can take place even under circumstances whereby the conducting portions are printed on basal surface (102, see e.g., FIG. 2) of the surface-complementary dielectric mask (RCM), 100 described herein.

Formulating the conducting ink composition may take into account the requirements, if any, imposed by the deposition tool (e.g., in terms of viscosity and surface tension of the composition) and the deposition surface characteristics (e.g., hydrophilic or hydrophobic, and the interfacial energy of the substrate or the support material (e.g., glass) if used), or the substrate layer on which consecutive layers are deposited. For example, the viscosity of either the conducting inkjet ink and/or the DI (measured at the printing temperature ° C.) can be, for example, not lower than about 5 cP, e.g., not lower than about 8 cP, or not lower than about 10 cP, and not higher than about 30 cP, e.g., not higher than about 20 cP, or not higher than about 15 cP. The conducting ink, can each be configured (e.g., formulated) to have a dynamic surface tension (referring to a surface tension when an ink-jet ink droplet is formed at the print-head aperture) of between about 25 mN/m and about 35 mN/m, for example between about 29 mN/m and about 31 mN/m measured by maximum bubble pressure tensiometry at a surface age of 50 ms and at 25° C. The dynamic surface tension can be formulated to provide a contact angle with the peelable substrate, the support material, the resin layer(s), or their combination, of between about 100° and about 165°.

In an exemplary implementation, the term “chuck” is intended to mean a mechanism for supporting, holding, or retaining a substrate or a workpiece. The chuck may include one or more pieces. In one exemplary implementation, the chuck may include a combination of a stage and an insert, a platform, be jacketed or otherwise be configured for heating and/or cooling and have another similar component, or any combination thereof.

In an exemplary implementation, the ink-jet ink compositions, systems and methods allowing for a direct, continuous or semi-continuous ink-jet printing of the surface-complementary dielectric mask (RCM), can be patterned by expelling droplets of the liquid ink-jet ink provided herein from an orifice one-at-a-time, as the print-head (or the substrate) is maneuvered, for example in two (X-Y dimensions) (it should be understood that the print head can also move in the Z axis), at a predetermined distance above the removable substrate or any subsequent layer. The height of the print head can be changed with the number of layers, maintaining for example a fixed distance. Each droplet can be configured to take a predetermined trajectory to the substrate on command by, for example a pressure impulse, via a deformable piezo-crystal in an exemplary implementation, from within a well operably coupled to the orifice. The printing of the first inkjet metallic ink can be additive and can accommodate a greater number of layers. The ink-jet print heads provided used in the methods described herein can provide a minimum layer film thickness equal to or less than about 0.3 μm-10,000 μm

The conveyor maneuvering among the various print heads used in the methods described and implementable in the systems described can be configured to move at a velocity of between about 5 mm/sec and about 1000 mm/sec. The velocity of the e.g., chuck can depend, for example, on: the desired throughput, the number of print heads used in the process, the number and thickness of layers of the surface-complementary dielectric mask (RCM), described herein printed, the curing time of the (dielectric) ink, the evaporation rate of the ink solvents, and the like or a combination of factors comprising one or more of the foregoing.

In an exemplary implementation, the volume of each droplet of the metallic (or metallic) ink, and/or the second, resin ink, can range from 0.5 to 300 picoLiter (pL), for example 1-4 pL and depended on the strength of the driving pulse and the properties of the ink. The waveform to expel a single droplet can be a 10V to about 70 V pulse, or about 16V to about 20V, and can be expelled at frequencies between about 2 kHz and about 500 kHz.

In certain exemplary implementations, the CAM module further comprises a computer program product for fabricating one or more surface-complementary dielectric mask. The printed surface-complementary dielectric mask can, under certain circumstances comprise both discrete metallic (conductive) components and resinous (insulating and/or dielectric) components thus, in effect, forming a topology circuit board automatically.

The computer controlling the printing process described herein can comprise: a computer readable storage medium having computer readable program code embodied therewith, the computer readable program code when executed by a processor in a digital computing device causes a three-dimensional inkjet printing unit to perform the steps of: pre-process Computer-Aided Design/Computer-Aided Manufacturing (CAD/CAM) generated information (e.g., Gerber and centroid files), associated with the PCB intended to undergo the reflow process, thereby creating a library of a plurality of 2D files (in other words, each file represents at least one, substantially 2D layer for printing the surface-complementary dielectric mask (RCM),); direct a stream of droplets of a DI resin material from a first inkjet print head at the surface of the substrate; move the substrate relative to the inkjet heads in an X-Y plane of the substrate, wherein the step of moving the substrate relative to the inkjet heads in the X-Y plane of the substrate, for each of a plurality of layers (and/or the patterns of DI inkjet inks within each layer), is performed in a layer-by-layer fabrication of the surface-complementary dielectric mask (RCM).

In addition, the computer program, can comprise program code means for carrying out the steps of the methods described herein, as well as a computer program product comprising program code means stored on a medium that can be read by a computer. Memory device(s) as used in the methods described herein can be any of various types of non-volatile memory devices or storage devices (in other words, memory devices that do not lose the information thereon in the absence of power). The term “memory device” is intended to encompass an installation medium, e.g., a CD-ROM, floppy disks, or tape device or a non-volatile memory such as a magnetic media, e.g., a hard drive, optical storage, or ROM, EPROM, FLASH, etc. The memory device may comprise other types of memory as well, or combinations thereof. In addition, the memory medium may be located in a first computer in which the programs are executed, and/or may be located in a second different computer which connects to the first computer over a network, such as the Internet. In the latter instance, the second computer may further provide program instructions to the first computer for execution. The term “memory device” can also include two or more memory devices which may reside in different locations, e.g., in different computers that are connected over a network. Accordingly, for example, the bitmap library can reside on a memory device that is remote from the CAM module coupled to the 3D inkjet printer provided, and be accessible by the 3D inkjet printer provided (for example, by a wide area network).

Unless specifically stated otherwise, as apparent from the following discussions, it is appreciated that throughout the specification discussions utilizing terms such as “processing,” “obtaining”, “repeating”, “loading,” “in communication,” “detecting,” “calculating,” “determining”, “analyzing,” or the like, refer to the action and/or processes of a computer or computing system, or similar electronic computing device, that manipulate and/or transform data represented as physical, such as a transistor architecture into other data similarly represented as physical structural (in other words, resin or metal/metallic) layers.

Furthermore, as used herein, the term “2D file library” refers to a given set of files that together define a single surface-complementary dielectric mask, or a plurality of surface-complementary dielectric masks. Furthermore, the term “2D file library” can also be used to refer to a set of 2D files or any other raster graphic file format (the representation of images as a collection of pixels, generally in the form of a rectangular grid, e.g., BMP, PNG, TIFF, GIF), capable of being indexed, searched, and reassembled to provide the structural layers of a given surface-complementary dielectric mask, whether the search is for the surface-complementary dielectric mask (RCM), as a whole, or a given specific layer within the surface-complementary dielectric mask (RCM).

The Computer-Aided Design/Computer-Aided Manufacturing (CAD/CAM) generated information associated with the surface-complementary dielectric mask (RCM), described herein to be fabricated, which is used in the methods, programs and libraries can be based on CAD/CAM data packages can be, for example, IGES, DXF, DWG, DMIS, NC files, GERBER® files, EXCELLON®, STL, EPRT files, an ODB, an ODB++, an .asm, an STL, an IGES, a STEP, a Catia, a SolidWorks, a Autocad, a ProE, a 3D Studio, a Gerber, a Rhino, a Altium, an Orcad, an Eagle file or a package comprising one or more of the foregoing, used to generate the surface-complementary dielectric mask (RCM). Additionally, attributes attached to the graphics objects (see e.g., FIG. 1A-1J) transfer the meta-information needed for fabrication and can precisely define the surface-complementary dielectric mask (RCM). Accordingly and in an exemplary implementation, using pre-processing algorithm, GERBER®, EXCELLON®, ODB++, Centroid, DWG, DXF, STL, EPRT ASM, and the like as described herein, are converted to 2D files' library for fabricating the surface-complementary dielectric mask (RCM).

A more complete understanding of the components, processes, assemblies, and devices disclosed herein can be obtained by reference to the accompanying drawings. These figures (also referred to herein as “FIG.s”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary implementations. Although specific terms are used in the following description for the sake of clarity, these terms are intended to refer only to the particular structure of the exemplary implementations selected for illustration in the drawings, and are not intended to define or limit the scope of the disclosure. In the drawings and the following description below, it is to be understood that like numeric designations refer to components of like function.

Turning to FIGS. 1A-3B, illustrating in FIG. 1A, illustrating the file image showing the PCB including SMT components sought to be coupled to the PCB during the reflow process. FIG. 1B, is an image of the outline/shape file of PCB 200 (see e.g., 201 FIG. 3A). For example, the board outline file (which could be separate or a part of the Gerber/ODB/ODB++ files, can be used for verifying the dimension of the board, and may include any cut-outs or external routing as well, which may be added to the surface-complementary dielectric mask (RCM), 100. FIG. 1C, shows the graphic image of the PCB board with the SMT component (see e.g., 204ᵢ FIG. 3A), or centroid file image. This file describes the position and orientation of all the surface mount (SMT) components, which includes the reference designator, X and Y position, rotation and side of Board (Top 203 or Bottom 202, see e.g., FIG. 3A). Only surface mounting parts are listed in the Centroid. FIG. 1D, represents the solder paste locations (see e.g., 205ⱼ FIG. 3A). This could be derived from the solder paste stencil file (e.g., Eagle file, *.brd), providing location for solder paste, which can be incorporated into the design (and/or cavities 104i) of the surface-complementary dielectric mask (RCM), (see e.g., 105ⱼ FIGS. 2, 3B). FIG. 1E, illustrates the drill file. This could be, for example an NC file (Excellon e.g.), can be used in conjunction with the GERBER® files to define the location of vias (PTH, Blind, Buried etc.) as well as drills for fasteners, NPTH and other purposes (see e.g., 206ₚ FIG. 3A), and used to define the location of protrusions in the surface-complementary dielectric mask (RCM), (see e.g., 106ₚ FIGS. 2, 3B), configured to engage the drill holes defined in the PCB's complementary surface.

Conversely, when fabricating the surface-complementary dielectric mask (RCM), the outline illustrated in FIG. 1F, can be fabricated using the outline file (see e.g., 101, FIGS. 2, 3B), and printed to a desired height between basal surface (see e.g., 102, FIGS. 2, 3B). In addition, as illustrated in FIG. 1G, SMT component section(s), constructed from the centroid file with the creation of cavities, voids, or recesses (see e.g., 104ᵢ, FIGS. 2, 3B), formed in apical surface (see e.g., 103, FIGS. 2, 3B), with the addition of a desired tolerance. FIG. 1H, illustrates the components with the pads and solder mask file (stencil) and can be constructed from the outline file in conjunction with, for example, the Eagle file e.g., with the creation of cavities (see e.g., 105ⱼ FIGS. 2, 3B), based on the component file and the (apical/basal) solder mask location file, printed to a desired height (depth) (see e.g., 105ᵢ, FIGS. 2, 3B), to ensure that the surface-complementary dielectric mask (RCM), will not touch the dispensed solder paste during assembly and smear the paste before reflow processing. Finally, FIG. 1I illustrates the fabrication of the protrusions (see e.g., 106ₚ, FIGS. 2, 3B), created from the drill file (e.g., numeric control (NC) drill file(s) (*.brd), Excellon). FIG. 1J illustrates the final result of the conversion of the data in the various files disclosed, to generate the substantial 2D files for printing the surface-complementary dielectric mask (RCM), (see e.g., 100, FIG. 2, 3B).

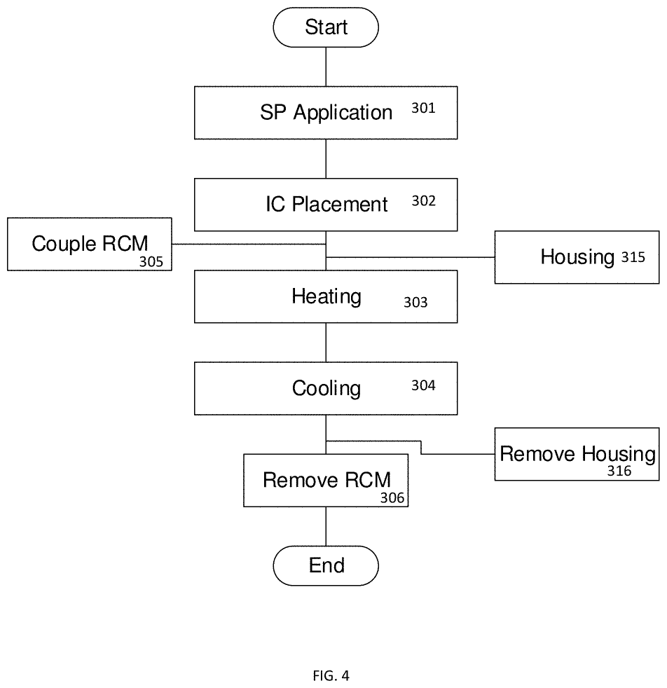

Turning now to FIG. 4, illustrating typical reflow process. As illustrated and in an exemplary implementation, the basic reflow solder process consists of: Application 301 of a solder paste to the desired pads on a printed circuit board (PCB), HFCP, or AME; placement 302 of the SMT components in the paste; applying heat 303 to the assembly which causes the solder in the paste to melt (reflow), wet the PCB (or HFCP, AME) and the part termination (cooling 304) resulting in the desired solder fillet connection. In an exemplary implementation, the surface-complementary dielectric mask (RCM), is coupled 305 to the corresponding complementary surface after the placement of the SMT component and before the application of heat, and removed 306 following the cooling stage. It is noted, that coupling the surface-complementary dielectric mask (RCM), to the corresponding complementary surface, can effectively encapsulate the SMT components and mitigate warpage, as well as prevent defects such as tombstoning of certain SMT components. In an exemplary implementation, following the step of coupling the RCM 305 to at least one surface of the PCB, HFCP, or AME, providing 315 a housing operable to accommodate the at least one RCM and the PCB, HFCP, or AME to which it is coupled, applying heat 303 to the housed assembly which causes the solder in the paste to melt (reflow), wet the surface of the PCB, HFCP, or AME and the part termination (cooling 304), resulting in the desired solder fillet connection and solidification, after which, the housing is removed 316, and the RCM is likewise separated and removed 306.

Tombstoning effect (also known as Manhattan effect, Drawbridge effect, or Stonehenge effect), in which a chip component is detached from the PCB at one end while remaining bonded to the circuit board at the opposite end, whereby the one end rises and the chip component assumes a more or less vertical orientation is considered a common soldering defect in surface mount electronic assembly of small leadless components such as resistors and capacitors. Accordingly, the systems and methods disclosed herein are used as methods for mitigating tombstoning effect of components in PCBs, HFCPs, or AMEs.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the print head(s) includes one or more print head). Reference throughout the specification to “one exemplary implementation”, “another exemplary implementation”, “an exemplary implementation”, and so forth, when present, means that a particular element (e.g., feature, structure, and/or characteristic) described in connection with the exemplary implementation is included in at least one exemplary implementation described herein, and may or may not be present in other exemplary implementations. In addition, it is to be understood that the described elements may be combined in any suitable manner in the various exemplary implementations. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly, in an exemplary implementation, provided herein is a computerized method of mitigating warpage of an assembled printed circuit board (PCB), high-frequency connect PCB (HFCP), or additively manufactured electronics (AME) during reflow processing, the method comprising: obtaining a plurality of files associated with the assembled PCB, HFCP, or AME, the assembled PCB, HFCP, or AME each having at least one of: an apical surface, and a basal surface; using the plurality of files, fabricating a surface-complementary dielectric mask (SCDM), or a reflow compression mask (RCM) to at least one of: the apical surface, and the basal surface; and prior to commencing the reflow processing, coupling the SCDM, or RCM to its complementary surface on the PCB, HFCP, or AME, thereby mitigating warpage during the reflow processing, wherein, (i) the plurality of files associated with the assembled PCB, HFCP, or AME comprise: a file configured to define an outline of the assembled PCB, HFCP, or AME; and a file configured to define dimensions and spatial arrangement of at least one surface-mounted integrated circuits (SMT) assembled on at least one of: the apical surface, and the basal surface of the PCB, HFCP, or AME sought to undergo reflow process, (ii) wherein the plurality of files associated with the assembled PCB, HFCP, or AME, further comprise at least one of: a file configured to define spatial parameters of solder paste dispensing; and an alignment file, (iii) the alignment file comprises spatial arrangement of non-plated drill holes, wherein (iv) the SCDM, or RCM, when coupled to at least one of: the apical surface, and the basal surface of the assembled PCB, HFCP, or AME, is operable to substantially encapsulate the at least one SMT, wherein (v) the step of fabricating the SCDM, or RCM, comprises: providing an ink jet printing system comprising: a first print head, operable to dispense a first dielectric ink composition; a conveyor, operably coupled to the first print head, operable to convey a substrate to the first print head; and a computer aided manufacturing (“CAM”) module including a central processing module (CPM), in communication with at least the conveyor and the first print head, the CPM further comprising at least one processor in communication with a non-transitory processor-readable storage medium storing thereon a set of executable instructions that, when executed by the at least one processor cause the CPM to control the ink-jet printing system, by carrying out steps that comprise: receiving at least one file associated with an assembled PCB, HFCP, or AME for which the SCDM, or RCM is sought to be fabricated; using the at least one file associated with an assembled PCB, HFCP, or AME, generating a file library comprising a plurality of files, each file representing a substantially 2D layer for printing the SCDM, or RCM; and a metafile representing at least the printing order; providing the first dielectric ink composition; using the CAM module, obtaining from the library a first file representative of the first layer for printing the SCDM, or RCM, wherein the first file comprises printing instructions for a pattern corresponding to the SCDM, or RCM; using the first print head, forming the pattern corresponding to the first dielectric ink; curing the pattern corresponding to the first dielectric ink representation in the first layer; using the CAM module, obtaining from the library, a subsequent file representative of a subsequent layer for printing the SCDM, or RCM, the subsequent file comprising printing instructions for a pattern corresponding to the first dielectric ink in the subsequent layer; repeating the steps of: using the first print head, forming the pattern corresponding to the first dielectric ink in the subsequent layer, to the step of using the CAM module, obtaining from the 2D file library the subsequent, substantially 2D layer, whereupon curing of the pattern corresponding to the first dielectric ink composition in the final layer in the printing order, the SCDM, or RCM comprises a plurality of cavities configured to complement at least one of: the apical surface, and the basal surface of the PCB, HFCP, or AME, substantially encapsulating any surface mounted components thereon: and removing the substrate, wherein (vi) the set of executable instructions is further configured, when executed, to cause the CAM module to: using the spatial parameters of solder paste dispensing, adapt the generated files in the library to generate patterns configured to, upon curing of the pattern corresponding to the first dielectric ink composition in the final layer in the printing order, form voids operable to accommodate the solder paste; and using the alignment file, adapt the generated pattern library to generate patterns configured to upon curing of the pattern corresponding to the first dielectric ink composition in the final layer in the printing order, form protrusions sized and configured to engage the non-plated drill holes, wherein (vii) upon curing of the pattern corresponding to the first dielectric ink composition in the final layer in the printing order, forming a frame sized to accommodate the outline of at least one of: the apical surface, and the basal surface of the PCB, HFCP, or AME sought to undergo reflow processing, wherein (viii) the first dielectric ink composition comprises polyester (PES), polyethylene (PE), polyvinyl alcohol (PVOH), poly(vinylacetate) (PVA), poly-methyl methacrylate (PMMA), Poly(vinylpirrolidone), a multi-functional acrylate, or a combination comprising a mixture, a monomer, an oligomer, and a copolymer of one or more of the foregoing, (ix) the multi-functional acrylate is at least one of a monomer, oligomer, polymer, and copolymer of: 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate or a multifunctional acrylate composition comprising one or more of the foregoing, wherein (x) the at least one SMT is mounted using reflow soldering process, (xi) the at least one SMT is a chip package that is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, wherein (xii) the PCB, HFCP, or AME are each comprising a plurality of SMT coupled to both the apical and basal surfaces of the PCB, HFCP, or AME, the method further comprises fabricating two dielectric surface masks: a first surface dielectric mask, complementary to the apical surface; and a second surface dielectric mask, complementary to the basal surface, (xiii) further comprising sandwiching the assembled PCB, HFCP, or AME between the first and second complementary dielectric surface masks, wherein (xiv) the complementary surface mask further comprises conductive traces and SMT and is operable as another PCB, HFCP, or AME, further comprising (xv) electrically coupling the complementary surface mask to its complementary surface, and wherein the method further comprising (xvi): following the step of coupling the SCDM, or RCM to its complementary surface on the PCB, HFCP, or AME, providing a housing operable to accommodate the SCDM, or RCM coupled to the PCB, HFCP, or AME; and commencing reflow processing.

In another exemplary implementation, provided herein is a computerized method for fabricating a complementary dielectric surface mask for an assembled printed circuit board (PCB), high-frequency connect PCB (HFCP), or additively manufactured electronics (AME) each having at least one surface mounted component (SMT) operably coupled to at least one of: an apical surface layer, and a basal surface layer, using inkjet printer, the method comprising: providing an ink jet printing system comprising: a first print head, operable to dispense a first dielectric ink composition; a conveyor, operably coupled to the first print head, configured to convey a substrate to the first print heads; and a computer aided manufacturing (“CAM”) module including a central processing module (CPM), in communication with at least the conveyor and the first print head, the CPM further comprising at least one processor in communication with a non-transitory processor-readable storage medium storing thereon a set of executable instructions that, when executed by the at least one processor cause the CPM to control the ink-jet printing system, by carrying out steps that comprise: receiving at least one file associated with an assembled PCB, HFCP, or AME for which the SCDM, or RCM is sought to be fabricated; using the at least one file associated with an assembled PCB, HFCP, or AME, generating a file library comprising a plurality of files, each file representing a substantially two-dimensional (2D) layer for printing the SCDM, or RCM and a metafile representing at least the printing order; providing the first dielectric ink composition; using the CAM module, obtaining from the library a first file representative of the first layer for printing the SCDM, or RCM, wherein the first file comprises printing instructions for a pattern corresponding to the SCDM, or RCM; using the first print head, forming the pattern corresponding to the first dielectric ink on the substrate; curing the pattern corresponding to the first dielectric ink representation in the first layer; using the CAM module, obtaining from the library, a subsequent file representative of a subsequent layer for printing the SCDM, or RCM, the subsequent file comprising printing instructions for a pattern corresponding to the first dielectric ink in the subsequent layer; repeating the steps of: using the first print head, forming the pattern corresponding to the first dielectric ink, to the step of using the CAM module, obtaining from the 2D file library the subsequent, substantially 2D layer, whereupon curing of the pattern corresponding to the first dielectric ink composition in the final layer in the printing order, the SCDM, or RCM comprises a plurality of cavities configured to complement the surface of the PCB, HFCP, or AME, substantially encapsulating the surface mounted components thereon; and remove the substrate, wherein (xvi) the surface-complementary dielectric mask (RCM), further comprises conductive traces and at least one SMT and is operable as a second PCB, HFCP, or AME, and wherein the method further comprises (xvi) the step of operably coupling the second PCB, HFCP, or AME to its complementary surface.

Although the foregoing disclosure for 3D printing of surface-complementary dielectric mask using inkjet printing based on various files has been described in terms of some exemplary implementations, other exemplary implementations will be apparent to those of ordinary skill in the art from the disclosure herein. Moreover, the described exemplary implementations have been presented by way of example only intended to clarify the technical features, and are not intended to limit the scope of the disclosure. Indeed, the novel methods, programs, libraries and systems described herein may be implemented in a variety of other forms without departing from the spirit thereof. Accordingly, other combinations, omissions, substitutions and modifications will be apparent to the skilled artisan in view of the disclosure herein.

1. A computerized method of mitigating warpage of an assembled printed circuit board (PCB), high-frequency connect PCB (HFCP), or additively manufactured electronics (AME) during reflow processing, the method comprising:
a. obtaining a plurality of files associated with the assembled PCB, HFCP, or AME, the assembled PCB, HFCP, or AME each having at least one of: an apical surface, and a basal surface;
b. using the plurality of files, fabricating a surface-complementary dielectric mask (SCDM), or a reflow compression mask (RCM) to at least one of: the apical surface, and the basal surface; and
c. prior to commencing the reflow processing, coupling the SCDM, or RCM to its complementary surface on the PCB, HFCP, or AME, thereby mitigating warpage during the reflow processing.

2. The method of claim 1, wherein the plurality of files associated with the assembled PCB, HFCP, or AME comprise:
a. a file configured to define an outline of the assembled PCB, HFCP, or AME; and
b. a file configured to define dimensions and spatial arrangement of at least one surface-mounted integrated circuits (SMT) assembled on at least one of: the apical surface, and the basal surface of the PCB, HFCP, or AME sought to undergo reflow process.

3. The method of claim 2, wherein the plurality of files associated with the assembled PCB, HFCP, or AME, further comprise at least one of:
a. a file configured to define spatial parameters of solder paste dispensing; and
b. an alignment file.

4. The method of claim 3, wherein the alignment file comprises spatial arrangement of non-plated drill holes.

5. The method of claim 4, wherein the SCDM, or RCM, when coupled to at least one of: the apical surface, and the basal surface of the assembled PCB, HFCP, or AME, is operable to substantially encapsulate the at least one SMT.

6. The method of claim 5, wherein, the step of fabricating the SCDM, or RCM, comprises:
a. providing an ink jet printing system comprising:
i. a first print head, operable to dispense a first dielectric ink composition;
ii. a conveyor, operably coupled to the first print head, operable to convey a substrate to the first print head; and
iii. a computer aided manufacturing (“CAM”) module including a central processing module (CPM), in communication with at least the conveyor and the first print head, the CPM further comprising at least one processor in communication with a non-transitory processor-readable storage medium storing thereon a set of executable instructions that, when executed by the at least one processor cause the CPM to control the ink-jet printing system, by carrying out steps that comprise:
1. receiving at least one file associated with an assembled PCB, HFCP, or AME for which the SCDM, or RCM is sought to be fabricated;
2. using the at least one file associated with an assembled PCB, HFCP, or AME, generating a file library comprising a plurality of files, each file representing a substantially 2D layer for printing the SCDM, or RCM; and
3. a metafile representing at least the printing order;
b. providing the first dielectric ink composition;
c. using the CAM module, obtaining from the library a first file representative of the first layer for printing the SCDM, or RCM, wherein the first file comprises printing instructions for a pattern corresponding to the SCDM, or RCM;
d. using the first print head, forming the pattern corresponding to the first dielectric ink;
e. curing the pattern corresponding to the first dielectric ink representation in the first layer;
f. using the CAM module, obtaining from the library, a subsequent file representative of a subsequent layer for printing the SCDM, or RCM, the subsequent file comprising printing instructions for a pattern corresponding to the first dielectric ink in the subsequent layer;
g. repeating the steps of: using the first print head, forming the pattern corresponding to the first dielectric ink in the subsequent layer, to the step of using the CAM module, obtaining from the 2D file library the subsequent, substantially 2D layer, whereupon curing of the pattern corresponding to the first dielectric ink composition in the final layer in the printing order, the SCDM, or RCM comprises a plurality of cavities configured to complement at least one of: the apical surface, and the basal surface of the PCB, HFCP, or AME, substantially encapsulating any surface mounted components thereon: and
h. removing the substrate.

7. The method of claim 6, wherein the set of executable instructions is further configured, when executed, to cause the CAM module to:
a. using the spatial parameters of solder paste dispensing, adapt the generated files in the library to generate patterns configured to, upon curing of the pattern corresponding to the first dielectric ink composition in the final layer in the printing order, form voids operable to accommodate the solder paste; and
b. using the alignment file, adapt the generated pattern library to generate patterns configured to upon curing of the pattern corresponding to the first dielectric ink composition in the final layer in the printing order, form protrusions sized and configured to engage the non-plated drill holes.

8. The method of claim 7, wherein upon curing of the pattern corresponding to the first dielectric ink composition in the final layer in the printing order, form a frame sized to accommodate the outline of at least one of: the apical surface, and the basal surface of the PCB, HFCP, or AME sought to undergo reflow processing.

9. The method of claim 6, wherein the first dielectric ink composition comprises polyester (PES), polyethylene (PE), polyvinyl alcohol (PVOH), poly(vinylacetate) (PVA), poly-methyl methacrylate (PMMA), Poly(vinylpirrolidone), a multi-functional acrylate, or a combination comprising a mixture, a monomer, an oligomer, and a copolymer of one or more of the foregoing.

10. The method of claim 9, wherein the multi-functional acrylate is at least one of a monomer, oligomer, polymer, and copolymer of: 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate or a multifunctional acrylate composition comprising one or more of the foregoing.

11. The method of claim 7, wherein the at least one SMT is mounted using reflow soldering process.

12. The method of claim 12, wherein the at least one SMT is a chip package that is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package.

13. The method of claim 12, wherein the PCB, HFCP, or AME are each comprising a plurality of SMT coupled to both the apical and basal surfaces of the PCB, HFCP, or AME, the method further comprises fabricating two dielectric surface masks:
a. a first surface dielectric mask, complementary to the apical surface; and
b. a second surface dielectric mask, complementary to the basal surface.

14. The method of claim 13, further comprising sandwiching the assembled PCB, HFCP, or AME between the first and second complementary dielectric surface masks.

15. The method of claim 7, or 13, wherein the complementary surface mask further comprises conductive traces and SMT and is operable as another PCB, HFCP, or AME.

16. The method of claim 15, further comprising electrically coupling the complementary surface mask to its complementary surface.

17. The method of claim 1, further comprising:
a. following the step of coupling the SCDM, or RCM to its complementary surface on the PCB, HFCP, or AME, providing a housing operable to accommodate the SCDM, or RCM coupled to the PCB, HFCP, or AME; and
b. commencing reflow processing.

18. A computerized method for fabricating a surface-complementary dielectric mask (SCDM), or reflow compression mask (RCM) for an assembled printed circuit board (PCB), high-frequency connect PCB (HFCP), or additively manufactured electronics (AME) each having at least one surface mounted component (SMT) operably coupled to at least one of: an apical surface layer, and a basal surface layer, using inkjet printer, the method comprising:
a. providing an ink jet printing system comprising:
i. a first print head, operable to dispense a first dielectric ink composition;
ii. a conveyor, operably coupled to the first print head, configured to convey a substrate to the first print heads; and
iii. a computer aided manufacturing (“CAM”) module including a central processing module (CPM), in communication with at least the conveyor and the first print head, the CPM further comprising at least one processor in communication with a non-transitory processor-readable storage medium storing thereon a set of executable instructions that, when executed by the at least one processor cause the CPM to control the ink-jet printing system, by carrying out steps that comprise:
1. receiving at least one file associated with an assembled PCB, HFCP, or AME for which the SCDM, or RCM is sought to be fabricated;
2. using the at least one file associated with an assembled PCB, HFCP, or AME, generating a file library comprising a plurality of files, each file representing a substantially two-dimensional (2D) layer for printing the SCDM, or RCM and a metafile representing at least the printing order;
b. providing the first dielectric ink composition;
c. using the CAM module, obtaining from the library a first file representative of the first layer for printing the SCDM, or RCM, wherein the first file comprises printing instructions for a pattern corresponding to the SCDM, or RCM;
d. using the first print head, forming the pattern corresponding to the first dielectric ink on the substrate;
e. curing the pattern corresponding to the first dielectric ink representation in the first layer;
f. using the CAM module, obtaining from the library, a subsequent file representative of a subsequent layer for printing the SCDM, or RCM, the subsequent file comprising printing instructions for a pattern corresponding to the first dielectric ink in the subsequent layer;
g. repeating the steps of: using the first print head, forming the pattern corresponding to the first dielectric ink, to the step of using the CAM module, obtaining from the 2D file library the subsequent, substantially 2D layer, whereupon curing of the pattern corresponding to the first dielectric ink composition in the final layer in the printing order, the surface-complementary dielectric mask (RCM), comprises a plurality of cavities configured to complement the surface of the PCB, HFCP, or AME, substantially encapsulating the surface mounted components thereon; and
h. remove the substrate.

19. The method of claim 18, wherein the SCDM, or RCM, further comprises conductive traces and at least one SMT coupled thereon to an external surface and is operable as a second PCB, HFCP, or AME.

20. The method of claim 19, further comprises the step of operably coupling the second PCB, HFCP, or AME to its complementary surface.
